(19) United States
(12) Patent Application Publication
(10) Pub. No.: US 2024/0025106 A1
(43) Pub. Date: Jan. 25, 2024

(54) CONTROL METHOD, MOLDING APPARATUS, AND ARTICLE MANUFACTURING METHOD

(71) Applicant: CANON KABUSHIKI KAISHA, Tokyo (JP)

(72) Inventor: KUNIHIKO ASADA, Tochigi (JP)

(21) Appl. No.: 18/343,833

(22) Filed: Jun. 29, 2023

(30) Foreign Application Priority Data
Jul. 19, 2022 (JP) 2022-115052

(51) Int. Cl. B29C 59/00; B29C 59/02

(52) U.S. Cl. CPC B29C 59/002; B29C 59/026; B29C 59/022; B29C 2059/023

(57) ABSTRACT

The present invention provides a method of executing a molding process of molding a composition on a substrate using a member, the method comprising: obtaining, by irradiating the substrate with light, an index indicating an intensity of reflected light from the substrate; determining, based on the index obtained in the obtaining, whether a predetermined preprocess necessary for executing the molding process has been executed on the substrate; and executing the molding process on the substrate in a case of determining that the preprocess has been executed on the substrate.

### BACKGROUND OF THE INVENTION

### Field of the Invention

The present invention relates to a control method, a molding apparatus, and an article manufacturing method.

### Description of the Related Art

With a demand for microfabrication of a semiconductor device, a Micro Electro Mechanical System (MEMS), and the like, there is known a molding technique of molding a composition on a substrate by bringing the composition and a mold into contact with each other. Such a molding technique is applicable to an imprint technique, a planarization technique, and the like. The imprint technique is a technique of curing a composition on a substrate in a state in which the composition is in contact with a mold including a pattern having concave and convex portions, thereby transferring the pattern of the mold to the composition on the substrate. The planarization technique is a technique of curing a composition on a substrate in a state in which the composition is in contact with a mold including a flat surface, thereby forming a film of the composition including a flat upper surface on the substrate.

Since such the molding technique can correctly transfer the shape of a mold to the composition on a substrate, it has attracted attention as a technique for finely and complicatedly molding the composition on a substrate. On the other hand, since the molding technique brings the mold and the composition on the substrate in direct contact, if an abnormality has occurred in the mold and/or the substrate, it is difficult to accurately mold the composition on the substrate. In addition, there is a risk of damaging the mold and/or the substrate. Japanese Patent Laid-Open No. 2016-207816 describes a method in which the image of the shot region to undergo an imprint process next, among a plurality of shot regions on a substrate, is captured to check the state of the shot region based on the obtained image, thereby preventing multiple imprinting.

In the molding technique, in order to accurately mold a composition on a substrate using a mold, various preprocesses can be executed on the substrate before bringing the mold and the composition on the substrate into contact with each other. Examples of the preprocess are application of a processing agent for promoting filling of the composition between the mold and the substrate, application of a processing agent for leaving the composition on the substrate side upon separating the mold from the cured composition, and the like. However, there can be a case in which the preprocess is not executed on the substrate, or a case in which the preprocess to be executed on the substrate is erroneous. In these cases, it can be difficult to accurately mold the composition on the substrate using the mold.

### SUMMARY OF THE INVENTION

The present invention provides, for example, a technique advantageous in avoiding execution of a molding process on a substrate having not undergone a preprocess properly.

According to one aspect of the present invention, there is provided a method of executing a molding process of molding a composition on a substrate using a member, the method comprising: obtaining, by irradiating the substrate with light, an index indicating an intensity of reflected light from the substrate; determining, based on the index obtained in the obtaining, whether a predetermined preprocess necessary for executing the molding process has been executed on the substrate; and executing the molding process on the substrate in a case of determining that the preprocess has been executed on the substrate.

Further features of the present invention will become apparent from the following description of exemplary embodiments with reference to the attached drawings.

### BRIEF DESCRIPTION OF THE DRAWINGS

FIG. 1 is a schematic view showing an arrangement example of an imprint apparatus of the first embodiment;

FIG. 2 is a flowchart illustrating a conventional control method of the imprint apparatus;

FIG. 3 is a flowchart illustrating a conventional substrate conveyance process;

FIG. 4 is a flowchart illustrating a control method of the imprint apparatus in the first embodiment (Example 1);

FIG. 5 is a view for explaining the allowable range of a reflection intensity index;

FIGS. 6A and 6B are graphs showing the change rate of the intensity of reflected light;

FIG. 7 is a flowchart illustrating a substrate conveyance process in the first embodiment (Example 3);

FIG. 8 is a schematic view showing an arrangement example of an imprint apparatus of the third embodiment;

FIG. 9 is a view showing an example of a substrate process that can effectively improve the throughput;

FIG. 10 is a flowchart showing a control example of a measurement area (measurement mechanism);

FIG. 11 is a flowchart showing a control example of each processing area (processing mechanism);

FIGS. 12A to 12F are views for explaining an article manufacturing method; and

FIGS. 13A to 13D are views for explaining a planarization process.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving (movement) concerning the X-axis, the Y-axis, and the Z-axis means control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

### First Embodiment

The first embodiment according to the present invention will be described. Examples of a molding apparatus that molds a composition on a substrate using a mold (member) are an imprint apparatus and a planarization apparatus. The imprint apparatus is an apparatus that brings a mold including a pattern having concave and convex portions into contact with a composition on a substrate, thereby forming (transferring) the pattern in the composition. The planarization apparatus is an apparatus that brings a mold including a flat surface into contact with a composition on a substrate, thereby planarizing the surface of the composition. In this embodiment, the imprint apparatus will be exemplified and described as the molding apparatus, but the arrangement and process described below are also applicable to the planarization apparatus.

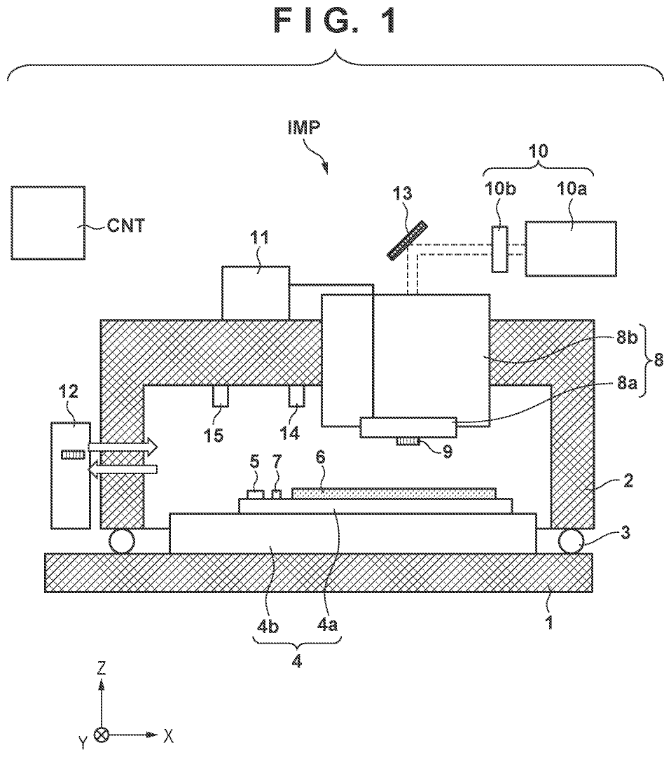

FIG. 1 is a schematic view showing an arrangement example of an imprint apparatus IMP of this embodiment. The imprint apparatus IMP is a lithography apparatus that is employed in a manufacturing step (lithography step) of a semiconductor device, a magnetic storage medium, a liquid crystal display apparatus, or the like. The imprint apparatus IMP functions as a molding apparatus that molds a curable composition on a substrate using a mold (member), and executes, as a molding process, an imprint process of molding an imprint material which is the curable composition. More specifically, as the imprint process, the imprint apparatus IMP brings the mold and the imprint material supplied onto the substrate into contact with each other and applies curing energy to the imprint material, thereby forming, on the substrate, a pattern of a cured product to which the pattern of the mold has been transferred. Note that the mold is also called a mold, a template, or an original.

The imprint apparatus IMP of this embodiment can include a substrate stage 4, an imprint head 8, a curing unit 10, an observation scope 14, a supply unit and a control unit CNT. The control unit CNT is formed from, for example, a computer (information processing apparatus) including a processor such as a Central Processing Unit (CPU) and a storage unit such as a memory, and controls the imprint process by controlling respective units of the imprint apparatus IMP.

The substrate stage 4 is configured to be capable of moving while holding a substrate 6. The substrate stage 4 of this embodiment includes a substrate chuck 4a and a substrate driving unit 4b. The substrate chuck 4a holds the substrate 6 by a vacuum force or the like. The substrate driving unit 4b drives the substrate chuck 4a (substrate 6) in the X and Y directions along the upper surface of a base 1. The X- and Y-direction positions of the substrate chuck 4a (substrate 6) can be detected by a detection unit (not shown) such as an interferometer or an encoder, and controlled based on the detection result of the detection unit. Here, the substrate stage 4 may be configured to drive the substrate 6 not only in the X and Y directions, but also in the Z direction and/or the θ direction (a rotational direction around the Z-axis).

A distance measurement sensor 7 capable of measuring the distance to a facing object is provided on the substrate stage 4. For example, the distance measurement sensor 7 can measure the height distribution of the surface of a mold 9 by measuring the distance to the surface (lower surface) of the mold 9 while moving in the X and Y directions together with the substrate stage 4. A reference mark 5 used to perform calibration of each unit of the imprint apparatus IMP is also provided on the substrate stage 4. Various marks exist on the reference mark 5. For example, the reference mark 5 can be used as the reference for the unit when executing initialization of the entire apparatus, and can be used when calibrating the position and state of the unit periodically during the operation of the apparatus. The image of the reference mark 5 can be captured (detected) by the observation scope 14 to be described later.

As the material of the substrate 6, for example, glass, ceramic, a metal, a semiconductor, a resin, or the like is used. A member made of a material different from that of the substrate 6 may be provided on the surface of the substrate 6, as needed. The substrate 6 is, for example, a silicon wafer, a semiconductor compound wafer, or silica glass.

As the imprint material to be supplied onto the substrate 6, a curable composition (to be also referred to as a resin in an uncured state) to be cured by receiving curing energy is used. The curable composition is a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The viscosity (the viscosity at 25° C.) of the viscous material is, for example, from 1 mPa·s (inclusive) to 100 mPa·s (inclusive).

In the imprint apparatus IMP of this embodiment, a frame 2 is provided on the base 1 via a damper 3 for reducing a vibration from the floor, and the imprint head 8 (imprint module) is attached to the frame 2. The imprint head 8 can include a mold holding unit 8a that holds the mold 9 by a vacuum force or the like, and a mold driving unit 8b that drives the mold holding unit 8a (mold) in the Z direction. By driving the mold 9 in the Z direction by the imprint head 8, a pressing process of pressing the mold 9 against the imprint material on the substrate 6, and a mold separation process of separating the mold 9 from the cured imprint material can be executed. Here, the imprint head 8 may be configured to drive the mold 9 not only in the Z direction but also in the X and Y directions and/or the θ direction (a rotational direction around the Z-axis). In addition, a flow path communicating with a gas supply mechanism 11 is provided in the imprint head 8, and an arbitrary gas can be supplied to the vicinity of the mold 9 via the flow path. Examples of the arbitrary gas are a gas such as helium gas or nitrogen gas for improving the fillability of the imprint material into the concave portions of the pattern of the mold 9 and/or a gas for suppressing inhibition of curing of the imprint material by oxygen.

The mold 9 has, for example, a rectangular outer shape, and can be usually made of a material such as quartz that can transmit ultraviolet light. A masa portion formed in a mesa shape having a step of, for example, about several tens of μm is provided on the substrate side of the mold 9. The surface of the mesa portion on the substrate side serves as a contact surface to be brought into contact with the imprint material on the substrate. The contact surface of the mold 9 used in the imprint apparatus IMP of this embodiment is formed as a pattern surface on which a pattern having concave and convex portions (device pattern or circuit pattern) to be transferred to the imprint material on the substrate has been formed. Note that the contact surface of a mold to be used in the planarization apparatus is formed as a flat surface on which a pattern having concave and convex portions has not been formed.

The mold 9 can be loaded/unloaded to/from the imprint head 8 via a mold storage unit 12. The mold storage unit 12 can include a receiving mechanism for receiving the mold 9 from the outside of the imprint apparatus IMP, an alignment mechanism for performing alignment (prealignment) of the mold 9 received by the receiving mechanism, and a conveyance mechanism that conveys the mold 9. After the mold 9 is aligned by the alignment mechanism, the mold 9 is conveyed to the imprint head 8 (mold holding unit 8a) by the conveyance mechanism.

The curing unit 10 is a mechanism that cures the imprint material on the substrate. Since the imprint apparatus IMP of this embodiment uses a photo-curable imprint material, the curing unit 10 can be configured to cure the imprint material on the substrate by irradiating the imprint material with light. The curing unit 10 includes a light source unit 10a that emits light of a wavelength which cures the imprint material, and a shutter 10b for switching irradiation/non-irradiation of light to the imprint material on the substrate. The light emitted from the light source unit 10a and having passed through the shutter 10b is applied to the imprint material on the substrate via a reflection unit 13 (mirror), the imprint head 8, and the mold 9.

The observation scope 14 is a mechanism that measures the shape of the substrate 6, the position of a mark formed on the substrate 6, and/or the height of the substrate 6, and can have a function of obtaining an image, a function of an optical sensor, and the like. The observation scope 14 is used to collect the information of the substrate 6 necessary for controlling the imprint process (for example, the information indicating the state of the substrate 6), perform a pattern overlay inspection of the cured product of the imprint material formed on the substrate by the imprint process, and the like. The observation scope 14 is used for various usages.

The observation scope 14 of this embodiment can function as a measurement unit that irradiates the substrate 6 with light and measures the index (to be sometimes referred to as a reflection intensity index hereinafter) indicating the intensity of reflected light from the substrate 6. For example, the observation scope 14 includes an illumination optical system including a light source, and an image capturing optical system including an image capturing element. The observation scope 14 can capture the image of the mark formed on the substrate 6 by the image capturing optical system while illuminating the mark by the illumination optical system, and measure the position and the reflection intensity index of the mark on the substrate 6 based on the image obtained thereby. Here, the observation scope 14 can be formed to include a processing unit that processes the image to obtain the reflection intensity index, but the processing unit may be formed as a part of the control unit CNT. Further, the observation scope 14 is only required to be attached to a position in the imprint apparatus IMP where the observation scope 14 can observe the substrate 6. For example, the observation scope 14 may be attached in the frame 2 or the imprint head 8, or in the path (the conveyance path of the substrate 6) of a conveyance mechanism (not shown) that conveys the substrate 6.

The supply unit 15 (dispenser) is a mechanism that supplies (discharges) the imprint material onto the substrate by discharging the imprint material toward the substrate 6. For example, in a state in which the substrate stage 4 is moving the substrate 6 below the supply unit 15, the supply unit 15 is caused to discharge the imprint material 3 as a plurality of droplets. Thus, the imprint material can be supplied onto the substrate. Note that in this embodiment, a photo-curable resin to be cured by light irradiation can be used as the imprint material.

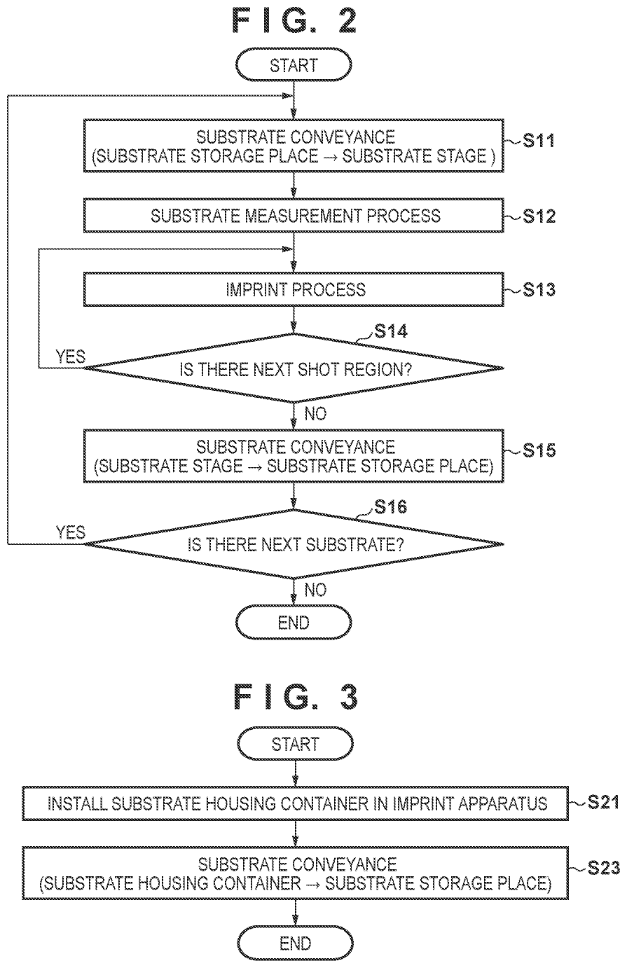

Next, a conventional control method of the imprint apparatus IMP will be described. FIG. 2 is a flowchart illustrating a conventional control method of the imprint apparatus IMP. Each step of the flowchart shown in FIG. 2 can be performed by the control unit CNT.

In step 811, the control unit CNT controls a substrate conveyance mechanism (not shown) to convey the substrate 6 as a target of the imprint process from a substrate storage place onto the substrate stage 4. The substrate storage place is a place in the imprint apparatus IMP where a plurality of the substrates 6 to undergo the imprint process are stored. More specifically, the substrate storage place is a place to which a plurality of substrates housed in a substrate housing container, which is called a Front Opening Unity Pod (FOUP), are conveyed and temporarily stored.

In step S12, the control unit CNT controls the substrate stage 4 to arrange the substrate 6 below the observation scope 14, and executes a substrate measurement process using the observation scope 14. The substrate measurement process is a process of measuring the substrate 6 to collect the information of the substrate 6 necessary for controlling the imprint process. For example, the substrate measurement process can include a process of capturing images of marks formed in a plurality of portions on the substrate 6, and measuring the position of the substrate 6 and/or the height/tilt of the substrate 6 based on the images obtained thereby. Based on the information obtained by the substrate measurement process, the control unit CNT can control (correct) the position, height, and/or tilt of the substrate 6. Control (correction) of the position, height, and/or tilt of the substrate 6 may be performed before an imprint process (step S13) (to be described later) is started, or may be performed during execution of the imprint process.

In step S13, the control unit CNT executes the imprint process on the target shot region on the substrate 6. The target shot region is a shot region, among the plurality of shot regions on the substrate 6, on which the imprint process is executed. In the imprint process, first, the supply unit 15 supplies the imprint material onto the target shot region (supply step). Then, the substrate stage 4 arranges the target shot region on the substrate 6 below the mold 9, the imprint head 8 lowers the mold 9, and the mold 9 is brought into contact with the imprint material on the substrate 6 (contact step). After the imprint material is filled into the concave portions of the pattern of the mold 9, in a state in which the mold 9 and the imprint material on the substrate 6 are in contact with each other, the curing unit 10 applies light to the imprint material on the substrate to cure the imprint material (curing step). Then, the imprint head 8 lifts the mold 9 to increase the spacing between the mold 9 and the substrate 6, thereby separating the mold 9 from the cured imprint material (mold separation step). With this, the pattern made of the cured product of the imprint material can be formed on the target shot region. Here, in this embodiment, the supply unit 15 provided in the imprint apparatus IMP supplies the imprint material onto the substrate. However, the present invention is not limited to this, and an external apparatus may supply the imprint material onto the substrate before the substrate 6 is loaded to the imprint apparatus IMP. In this case, the substrate with the imprint material supplied (applied) thereon is loaded to the imprint apparatus IMP, and the supply step is omitted.

In step S14, the control unit CNT determines whether there is a shot region (next shot region) to undergo the imprint process next on the substrate 6. If there is a next shot region, the process returns to step S13, and the imprint process is executed on the next shot region serving as the target shot region. On the other hand, if there is no next shot region, the process advances to step S15.

In step S15, the control unit CNT controls the substrate conveyance mechanism (not shown) to convey the substrate 6 from the substrate stage 4 to the substrate storage place. Then, in step S16, the control unit CNT determines whether there is a substrate (next substrate) to undergo the imprint process next in the substrate storage place. If there is the next substrate, the process returns to step S11. That is, steps S11 to S16 are repeated until the imprint process on each of the plurality of substrates stored in the substrate storage place is completed. On the other hand, if there is no next substrate, the process ends.

Next, a process (substrate conveyance process) of conveying the substrate 6 to the imprint apparatus IMP before starting the flowchart shown in FIG. 2 will be described. FIG. 3 is a flowchart illustrating a conventional substrate conveyance process.

In step S21, a substrate housing container (for example, FOUP) is installed (coupled or arranged) in the imprint apparatus IMP. In step S22, a plurality of the substrates 6 housed in the substrate housing container are conveyed to the substrate storage place of the imprint apparatus IMP by the substrate conveyance mechanism (not shown). Each of the plurality of the substrates 6 conveyed to the substrate storage place can be sequentially conveyed onto the substrate stage 4 and undergo the imprint process in accordance with the flowchart of FIG. 2. Whether conveying the substrate 6 temporarily to the substrate storage place from the substrate housing container or conveying the substrate 6 directly to the substrate stage 4 from the substrate housing container can be selected in accordance with the configuration of the imprint apparatus IMP, or the input of setting of the user who uses the imprint apparatus IMP. If the imprint processes for all of the substrates 6 are completed faster by conveying the substrates 6 temporarily to the substrate storage place than by conveying the substrates 6 directly to the substrate stage 4, conveying the substrates 6 temporarily to the substrate storage place is superior in terms of productivity. On the other hand, conveying the substrates 6 directly to the substrate stage 4 is superior in a case in which, for example, due to the characteristics of the external process (preprocess) executed on the substrate 6, it is necessary to execute the imprint process immediately after the external process and so it is desirable to reduce the conveyance time to the substrate storage place.

In order to accurately form the pattern of the imprint material on the substrate 6 in the imprint apparatus IMP, a predetermined preprocess necessary for executing the imprint process (molding process) can be executed on the substrate 6. The preprocess can be executed outside the imprint apparatus. Examples of the preprocess are application of a processing agent for promoting filling of the imprint material between the mold 9 and the substrate 6, application of a processing agent for leaving the imprint material on the substrate side upon separating the mold 9 from the cured imprint material, and the like. As an example, the preprocess can include forming an adhesive layer for adhering the substrate 6 and the imprint material each other, forming a planarized film such as an SOC (Spin On Carbon) film, and/or a lyophilization process of lyophilizing the surface of the substrate 6 with respect to the imprint material. If the imprint material is supplied onto the substrate outside the imprint apparatus IMP, the preprocess may include supplying the imprint material onto the substrate. The preprocess can be set (decided), as appropriate, in accordance with the material of the substrate 6, the manufacturing process, and the like.

However, there can be a case in which the preprocess is not executed on the substrate 6, or a case in which the preprocess to be executed on the substrate 6 is erroneous. In these cases, it can be difficult to accurately form the pattern of the imprint material on the substrate 6. Therefore, in this embodiment, by utilizing a phenomenon that the light absorption rate of the substrate 6 changes when the preprocess of the substrate 6 changes, it is determined whether the predetermined preprocess necessary for executing the imprint process has been executed on the substrate 6. More specifically, the substrate 6 is irradiated with light to measure the reflection intensity index of the substrate 6 and, based on the measured reflection intensity index, it is determined whether the predetermined preprocess has been executed on the substrate 6. If it is determined that the predetermined process has been executed on the substrate 6, the imprint process is executed on the substrate 6. With this, it is possible to avoid that the imprint process (molding process) is executed on the substrate 6 which has not undergone the preprocess properly. Examples of this embodiment will be described below.

### Example 1

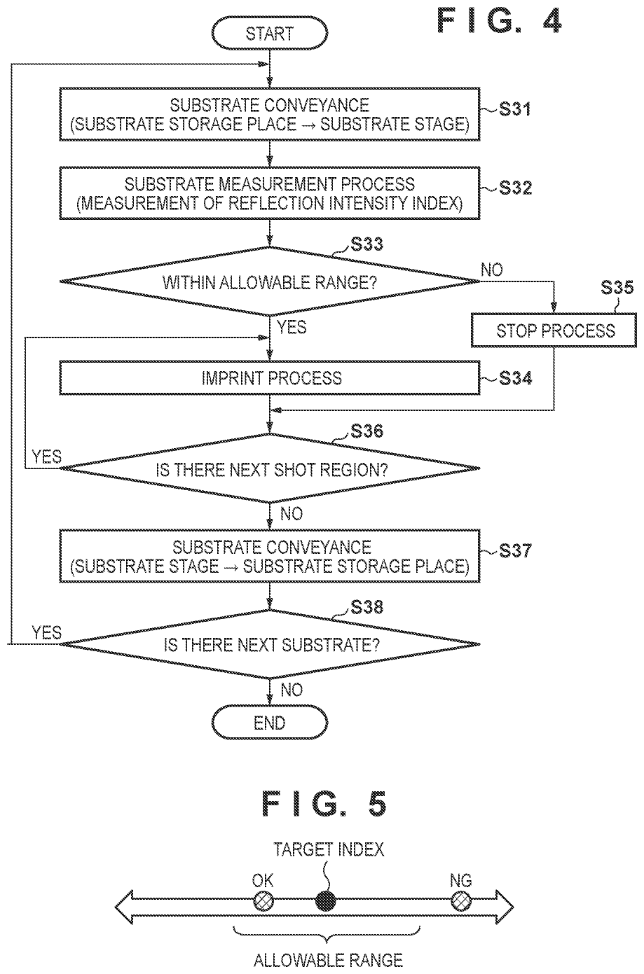

FIG. 4 is a flowchart illustrating a control method of the imprint apparatus IMP (imprint process) in Example 1. Each step of the flowchart shown in FIG. 4 can be performed by the control unit CNT.

In step S31, the control unit CNT controls the substrate conveyance mechanism (not shown) to convey the substrate 6 as a target of the imprint process from the substrate storage place onto the substrate stage 4. Since step S31 is a step similar to step S11 of FIG. 2 described above, a detailed description is omitted here.

In step S32, the control unit CNT controls the substrate stage 4 to arrange the substrate 6 below the observation scope 14, and executes a substrate measurement process using the observation scope 14. As has been described above, the substrate measurement process is a process of measuring the substrate 6 to collect the information of the substrate 6 necessary for controlling the imprint process. The substrate measurement process can include, for example, a process of capturing images of marks formed in a plurality of portions on the substrate 6, and measuring the position, height, and/or tilt of the substrate 6 based on the images obtained thereby.

Here, in addition to the process similar to step S12 of FIG. 2 described above, the substrate measurement process in step S32 further includes a process of irradiating the substrate 6 with light and measuring the reflection intensity index of the substrate 6. That is, in step S32, the control unit CNT measures the reflection intensity index using the observation scope 14.

The preprocess of the substrate 6 can be changed in accordance with the kind and characteristics of the device (article) to be manufactured and the contents of the imprint process to be executed. If the preprocess executed on the substrate 6 changes, the light reflectance of the substrate 6 changes accordingly. Therefore, the reflection intensity index is a unique (specific) value corresponding to the preprocess of the substrate 6. Hence, by measuring the reflection intensity index, it can be determined (checked), based on the measurement result, whether the predetermined preprocess necessary (appropriate) for executing the imprint process has been executed on the substrate 6.

For example, the control unit CNT can measure the reflection intensity index using data (image) obtained to measure the position of the substrate 6 by the substrate measurement process. More specifically, the control unit CNT can capture an image of the substrate 6 by the observation scope 14, and measure, as the reflection intensity index, at least one of the illuminance and contrast of the image obtained thereby. In Example 1, the control unit CNT can measure, as the reflection intensity index, at least one of the illuminance and contrast of an image obtained by capturing the image of the mark on the substrate 6 by the observation scope 14.

Alternatively, the control unit CNT may obtain the reflection intensity index using data (image) obtained to measure the height and tilt of the substrate 6 by the substrate measurement process. Measurement of the height and tilt of the substrate 6 is often executed on a portion as flat as possible, because a misleading (error) can occur in the measurement result on a portion with a step such as the mark. Scattering of light is less likely to occur on the flat portion than on the portion with a step such as the mark, so that an error is less likely to occur in the reflection intensity index measured by the observation scope 14. That is, the reflection intensity index can be accurately measured. In this manner, if the reflection intensity index is obtained using data obtained to measure the position, height, or tilt of the substrate 6, it is unnecessary to additionally execute measurement of the reflection intensity index separately from measurement of the position or the like of the substrate 6. That is, it is possible to measure the reflection intensity index while preventing a degradation in productivity in the imprint apparatus IMP.

In step S33, the control unit CNT determines whether the reflection intensity index measured in step S32 falls within an allowable range. If the reflection intensity index falls within the allowable range, the control unit CNT determines that the predetermined preprocess necessary for executing the imprint process has been executed on the substrate 6, and advances to step S34. On the other hand, if the reflection intensity index falls outside the allowable range, the control unit CNT determines that the predetermined preprocess has not been executed on the substrate 6, and advances to step S35.

As shown in FIG. 5, the allowable range used in step S33 can be set to the range obtained by adding a margin to the reflection intensity index (to be sometimes referred to as the target index hereinafter) to be obtained when the predetermined preprocess has been executed. The target index can be set to, for example, the reflection intensity index measured with respect to a reference substrate on which the predetermined preprocess has been reliably executed. As the reference substrate, a substrate can be used which is made of the same material as the substrate 6 to be the target of the imprint process, and on which the imprint process has not been executed yet. For example, the first substrate to undergo the imprint process in a lot including a plurality of the substrates 6 may be used as the reference substrate. Note that the target index may be set using a plurality of reference substrates. Since an error can occur in the predetermined preprocess for each substrate, the variation amount of the reflection intensity index caused by the error is obtained (grasped) in advance, and the variation amount can be set as the margin. In Example 1, the allowable range is set using the reference substrate. However, the present invention is not limited to this, and the allowable range may be set based on a simulation result.

The control unit CNT may update the allowable range by executing machine learning for a plurality of substrates while using the measurement value of the reflection intensity index and the imprint result (for example, the determination result as to whether the predetermined preprocess has been executed) as training data. For example, if the imprint process is executed on each of a plurality of (a large number of) substrates, by automatically updating the allowable range using machine learning, the accuracy of determination as to whether the predetermined preprocess has been executed on the substrate 6 can be improved.

Here, if the substrate measurement process is executed for each of the plurality of portions (for example, a plurality of marks) on the substrate 6 in step S32, the reflection intensity index may be measured for each of the plurality of portions. In this case, in step S33, the control unit CNT may determine, based on whether the representative value of the reflection intensity indices obtained for the plurality of portions falls within the allowable range, whether the predetermined preprocess has been executed on the substrate 6. As the representative value of the reflection intensity indices, for example, the average value, median, or mode of the reflection intensity indices obtained for the plurality of portions can be used.

In step S34, the control unit CNT executes the imprint process on the target shot region on the substrate 6. Since step S34 is a step similar to step S13 of FIG. 2 described above, a detailed description is omitted here. On the other hand, in step S35, the control unit CNT executes a stop process of stopping execution of the imprint process on the substrate 6. The stop process can include notifying that the predetermined preprocess has not been executed on the substrate 6. This notification can be executed, for example, by displaying, on the user interface (display) of the imprint apparatus IMP, information indicating that the predetermined preprocess has not been executed, or transmitting the information to the computer (information processing apparatus) of an operator.

In step S36, the control unit CNT determines whether there is a next shot region on the substrate 6. If there is a next shot region, the process returns to step S34. If there is no next shot region, the process advances to step S37. In step S37, the control unit CNT controls the substrate conveyance mechanism (not shown) to convey the substrate 6 from the substrate stage 4 to the substrate storage place. Then, in step S38, the control unit CNT determines whether there is the next substrate in the substrate storage place. If there is the next substrate, the process returns to step S31. If there is no next substrate, the process ends. Since steps S36 to S38 are steps similar to steps S14 to S16 of FIG. 2 described above, respectively, a detailed description is omitted here.

Here, FIG. 4 shows the example in which steps S31 to S38 are performed on each of the plurality of the substrates 6, but the present invention is not limited to this. For example, if it is determined in step S33 that the reflection intensity index of one substrate 6 of the plurality of the substrates 6 falls outside the allowable range, the control unit CNT may cancel (stop) the imprint process (that is, steps S31 to S38) for subsequent substrates. Further, if it is determined that the reflection intensity index of the first substrate to undergo the imprint process in the lot falls within the allowable range, it may be assumed that the reflection intensity indices of subsequent substrates also fall within the allowable range, and the reflection intensity indices of the subsequent substrates may not be measured. In this case, for the subsequent substrate, the process advances to step S34 without performing step S33.

### Example 2

In Example 1 described above, the example has been described in which at least one of the illuminance and contrast of an image obtained by capturing the image of the substrate 6 by the observation scope 14 is measured as the reflection intensity index. In Example 2, another example of the reflection intensity index will be described. Note that Example 2 basically takes over Example 1 described above, and can follow Example 1 except matters to be described below.

In Example 2, an example will be described in which the change rate of the intensity of the reflected light obtained by changing an irradiation condition for irradiating the substrate 6 with light is measured as the reflection intensity index. The irradiation condition can include at least one of the intensity and wavelength of light with which the substrate 6 is irradiated. In Example 2, an example of changing the intensity of light with which the substrate 6 is irradiated as the irradiation condition will be described.

In the substrate measurement process in step S32 of FIG. 4, the control unit CNT measures the intensity of the reflected light from the substrate 6 while changing, as the irradiation condition, the intensity of light (irradiation light) with which the substrate 6 is irradiated from the observation scope 14. With this, the control unit CNT can measure, as the reflection intensity index, the change rate (tilt amount) of the intensity of the reflected light with respect to the change of the intensity of the irradiation light. By measuring, as the reflection intensity index, the change rate of the intensity of the reflected light in this manner, even in a case in which the intensity of the reflected light varies among multiple substrates having undergone the same preprocess, it is possible to reduce a variation of the reflection intensity index among the multiple substrates. That is, the accuracy of determination as to whether the predetermined preprocess has been executed can be improved. Here, the intensity of the irradiation light as the irradiation condition is not limited to be changed continuously, but may be changed stepwise. That is, the control unit CNT may measure the intensity of the reflected light from the substrate 6 for each of a plurality of states among which the intensity of the irradiation light is changed.

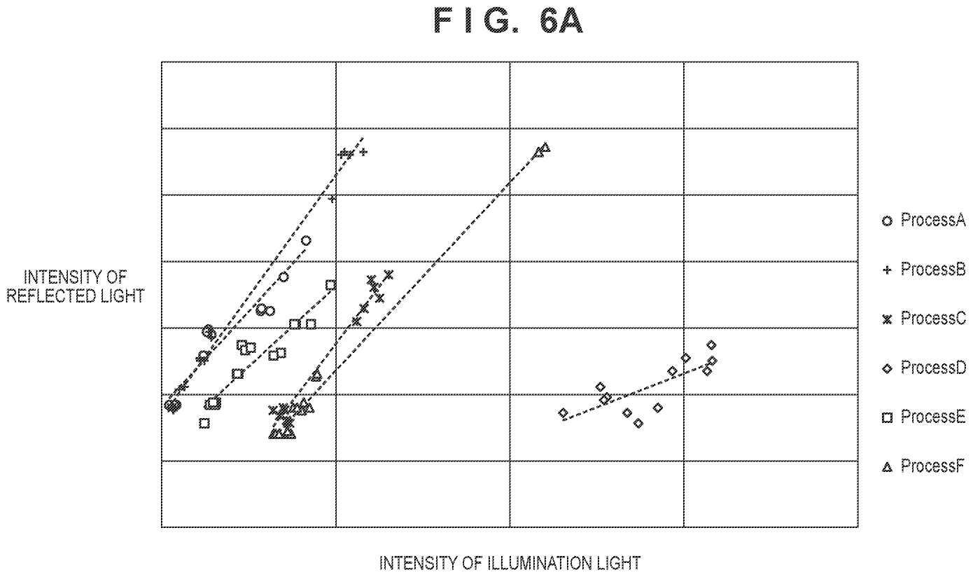

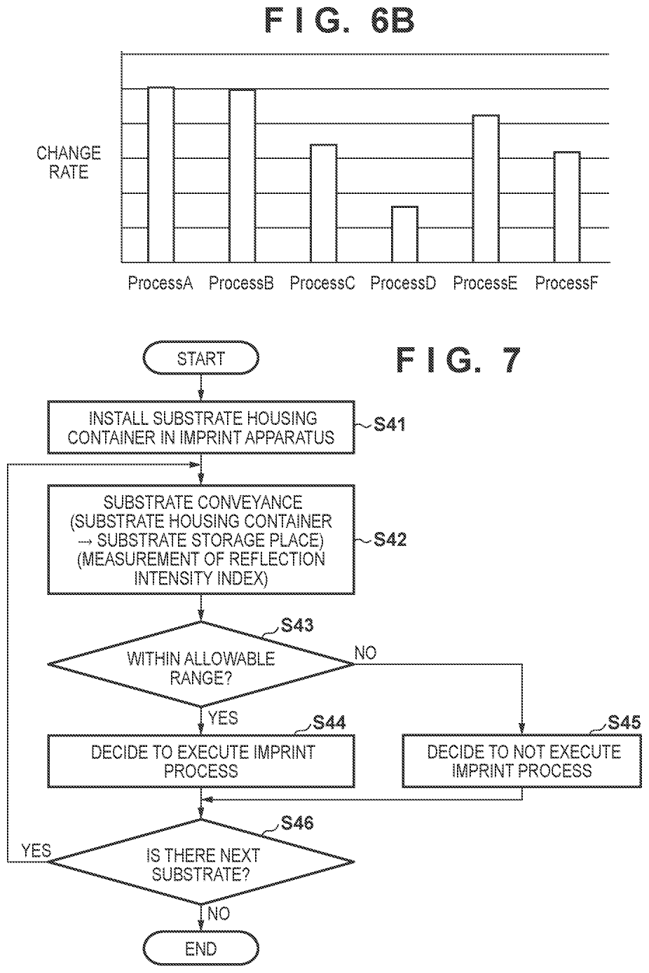

FIGS. 6A and 6B are graphs showing the change rate of the intensity of reflected light. FIG. 6A is a graph in which the abscissa represents the intensity of the irradiation light, the ordinate represents the intensity of the reflected light, and the measurement value of the intensity of the reflected light is plotted. In FIG. 6A, the measurement values of the intensities of the reflected light beams for six different kinds of preprocesses (Process A to Process F) are shown. As shown in FIG. 6A, it can be seen that if the preprocess of the substrate changes, the change rate (tilt amount or coefficient) of the intensity of the reflected light with respect to the change of the intensity of the irradiation light changes accordingly. FIG. 6B is a graph in which the change rates of the intensities of the reflected light beams obtained in FIG. 6A are compared among the six kinds of preprocesses (Process A to Process F). As shown in FIG. 6B, the change rate of the intensity of the reflected light changes in accordance with the preprocess. Therefore, by using the change rate as the reflection intensity index, it is possible to accurately determine whether the predetermined preprocess has been executed.

### Example 3

In Examples 1 and 2 described above, the example has been described in which the reflection intensity index of the substrate 6 is measured in a state in which the substrate 6 is held by the substrate stage 4. However, the reflection intensity index may be measured in the substrate conveyance process described above with reference to FIG. 3. In Example 3, an example will be described in which the reflection intensity index is measured in the substrate conveyance process. FIG. 7 is a flowchart illustrating the substrate conveyance process including measurement of the reflection intensity index. Note that Example 3 basically takes over Example 1 described above, and can follow Example 1 except matters to be described below. Example 3 may take over Example 2 described above.

In step S41, the substrate housing container (for example, FOUP) is installed (coupled or arranged) in the imprint apparatus IMP. Then, in step S42, the control unit CNT conveys the substrate 6 from the substrate housing container to the substrate storage place of the imprint apparatus IMP by the substrate conveyance mechanism (not shown). In Example 3, in the process of conveying the substrate 6 from the substrate housing container to the substrate storage place of the imprint apparatus IMP, the substrate 6 is arranged within the observation visual field (within the image capturing visual field) of the observation scope 14. Therefore, in step S42, the control unit CNT can measure the reflection intensity index of the substrate 6 by the observation scope 14.

In step S43, the control unit CNT determines whether the reflection intensity index measured in step S42 falls within an allowable range. If the reflection intensity index falls within the allowable range, the control unit CNT determines that the predetermined preprocess necessary for executing the imprint process has been executed on the substrate 6, and advances to step S44. In step S44, the control unit CNT decides to execute the imprint process on the substrate 6 being conveyed. On the other hand, if the reflection intensity index falls outside the allowable range, the control unit CNT determines that the predetermined preprocess has not been executed on the substrate 6, and advances to step S45. In step S45, the control unit CNT decides not to execute the imprint process on the substrate 6 being conveyed. Further, in step S45, as in step S35 of FIG. 4, it may be notified that the predetermined preprocess has not been executed on the substrate 6.

In step S46, the control unit CNT determines whether there is a substrate (next substrate) in the substrate housing container, which is to be conveyed to the substrate storage place next. If there is the next substrate, the process returns to step S42. If there is no next substrate, the process ends. In this manner, by determining in the substrate conveyance process whether the predetermined preprocess has been executed, it is possible to early grasp the substrate having not undergone the predetermined process. Here, the example has been described in Example 3 in which the reflection intensity index of the substrate 6 is measured in the process of conveying the substrate 6 from the substrate housing container to the substrate storage place of the imprint apparatus IMP, but the reflection intensity index of the substrate 6 may be measured in a process of conveying the substrate 6 onto the substrate stage 4.

As has been described above, in this embodiment (Examples 1 to 3), the substrate 6 is irradiated with light to measure the reflection intensity index and, based on the reflection intensity index, it is determined whether the predetermined preprocess necessary for executing the imprint process has been executed on the substrate 6. If it is determined that the predetermined process has been executed on the substrate 6, the imprint process is executed on the substrate 6. With this, it is possible to avoid that the imprint process (molding process) is executed on the substrate 6 having not undergone the predetermined preprocess properly.

### Second Embodiment

The second embodiment according to the present invention will be described. This embodiment basically takes over the first embodiment, and can follow the first embodiment except matters to be described below.

In an observation scope 14 used to measure the reflection intensity index of a substrate 6, the intensity of illumination light and the light receiving sensitivity (image capturing sensitivity) with respect to reflected light may change due to aging, maintenance, replacement, or the like. In this case, it can become difficult to accurately measure the reflection intensity index of the substrate 6 using the observation scope 14. That is, it can become difficult to accurately determine, based on the reflection intensity index of the substrate 6, whether a predetermined preprocess has been executed on the substrate 6.

To solve this problem, in this embodiment, a calibration process of calibrating the measurement condition for measuring the reflection intensity index in the substrate measurement process in step S32 of FIG. 4 is executed before the substrate measurement process. In the calibration process, the measurement condition is calibrated such that the reflection intensity index measured for a member (object) different from the substrate 6 matches a target value (falls within a target range). The measurement condition is, for example, a condition for measuring the reflection intensity index of the substrate 6 by the observation scope 14. Examples of the measurement condition are the intensity of the irradiation light with which the substrate 6 is irradiated from the observation scope 14, the gain applied to the image capturing element (photoelectric conversion element) of the observation scope 14, and the like. The “member different from the substrate 6” used to calibrate the measurement condition is a reference member that can obtain the reflection intensity index serving as a reference. As the reference member, for example, a reference mark 5 provided on a substrate stage 4 can be used.

For example, the calibration process may be executed for every predetermined number of substrates, or may be executed every time a certain period of time elapses. Alternatively, the calibration process may be executed every time for each substrate before the substrate measurement process in step S32 of FIG. 4. The calibration process can be executed between steps S31 and S32 of FIG. 4, but may be executed before step S31 of FIG. 4. For example, the calibration process may be executed before the flowchart of FIG. 4 is started for the first substrate in a lot.

By executing the calibration process as described above, it is possible to accurately measure the reflection intensity index of the substrate. Accordingly, the accuracy of determination as to whether the predetermined preprocess has been executed on the substrate 6 can be improved.

### Third Embodiment

The third embodiment according to the present invention will be described. In an imprint apparatus IMP, since an improvement in throughput is demanded, it is preferable that imprint processes are executed in parallel on two or more substrates 6. Therefore, in this embodiment, the imprint apparatus IMP including a plurality of processing areas for executing the imprint processes will be described. Note that this embodiment basically takes over the first embodiment, and can follow the first embodiment except matters to be described below. This embodiment may take over the second embodiment.

FIG. 8 is a schematic view showing an arrangement example of the imprint apparatus IMP of this embodiment. The imprint apparatus IMP of this embodiment can include a plurality of processing areas 21 (processing stations, processing unit) and a measurement area 22 (measurement station). A processing mechanism that executes the imprint process on the substrate 6 is provided in each of the plurality of processing areas 21. The processing mechanism can include, for example, a substrate stage 4, an imprint head 8, a curing unit 10, and the like as in the arrangement shown in FIG. 1. A measurement mechanism that executes a substrate measurement process is provided in the measurement area 22. The measurement mechanism includes, for example, an observation scope 14 (measurement unit), and measures the reflection intensity index of the substrate 6. The imprint apparatus IMP of this embodiment also includes a control unit CNT that controls the processing mechanisms in the respective processing areas 21 and the measurement mechanism in the measurement area 22. The control unit CNT is formed from, for example, a computer including a processor such as a CPU and a storage unit such as a memory, and controls each unit of the imprint apparatus IMP.

Four processing areas 21 and one measurement area 22 are provided in the imprint apparatus IMP shown in FIG. 8. By providing the plurality (four) of processing areas 21 with respect to one measurement area 22 in this manner, it is possible to assign the substrates each having undergone measurement of the reflection intensity index in the measurement area 22 to the respective processing areas 21, and execute imprint processes in the plurality of processing areas 21 in parallel. That is, the throughput (productivity) of the imprint apparatus IMP can be improved. For example, if the time of the substrate measurement process executed on one substrate 6 in the measurement area 22 is shorter than the time of the imprint process executed on one substrate 6 in each processing area 21, this embodiment can be advantageous in terms of throughput. In the example shown in FIG. 8, if the time of the substrate measurement process is substantially ¼ the time of the imprint process, the utilization rate of each processing area 21 and the utilization rate of the measurement area 22 reach close to 100%, and this embodiment can be particularly advantageous in terms of throughput.

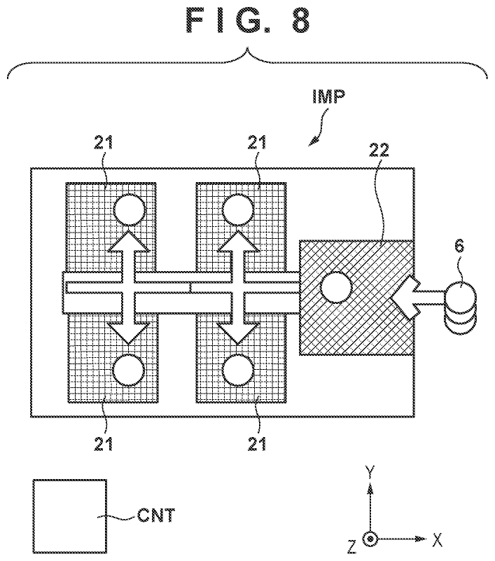

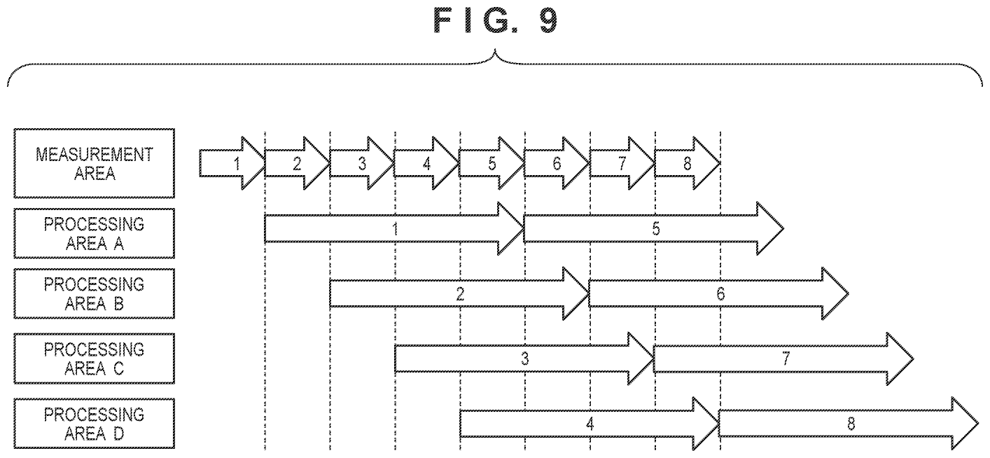

FIG. 9 shows an example of a substrate process that can effectively improve the throughput in the arrangement of the imprint apparatus IMP shown in FIG. 8. In FIG. 9, the length of a block arrow represents the time of the process (substrate measurement process or imprint process), and the number appended to each block arrow indicates the number of the substrate. For example, the number “1” indicates the first substrate. Note that the conveyance time of the substrate to each area is included in the processing time in the area.

In the imprint apparatus IMP of this embodiment, the first substrate is conveyed to a processing area A after undergoing the substrate measurement process in the measurement area, and undergoes the imprint process in the processing area A. The second substrate is conveyed to a processing area B after undergoing the substrate measurement process in the measurement area, and undergoes the imprint process in the processing area B. Similarly, the third substrate and the fourth substrate undergo the substrate measurement process in the measurement area, and then undergo the imprint processes in a processing area C and a processing area D, respectively. Here, it is preferable that the substrate measurement process of the fifth substrate in the measurement area is completed at the timing of completion of the imprint process on the first substrate in the processing area A. In this case, immediately after the first substrate is conveyed from the processing area A, the fifth substrate can be conveyed to the processing area A. Thus, a decrease in utilization rate of the processing area A can be suppressed. This also applies to the sixth and subsequent substrates. In this manner, if the time of the substrate measurement process in the measurement area is 1/n the time of the imprint process in the processing area, when the number of the processing areas is n times the number of the measurement areas, the throughput can be effectively improved.

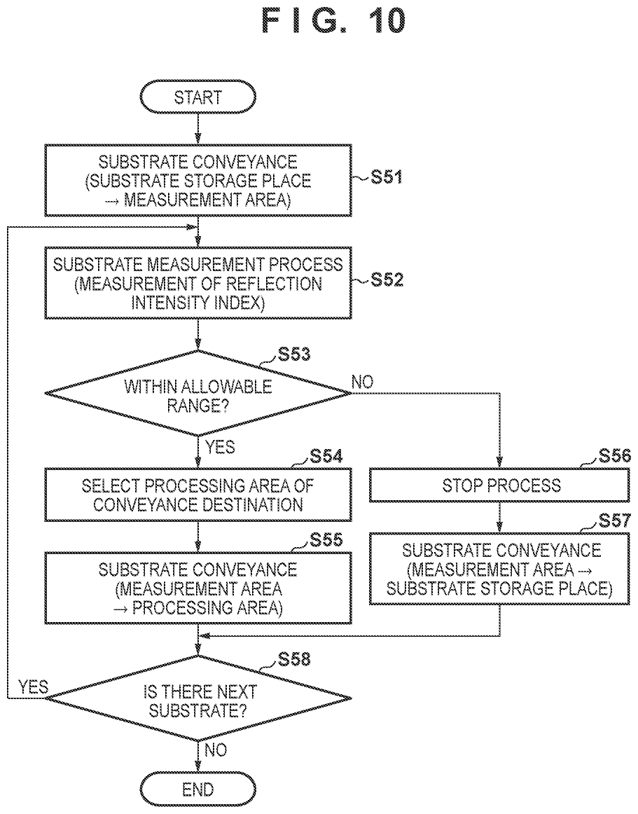

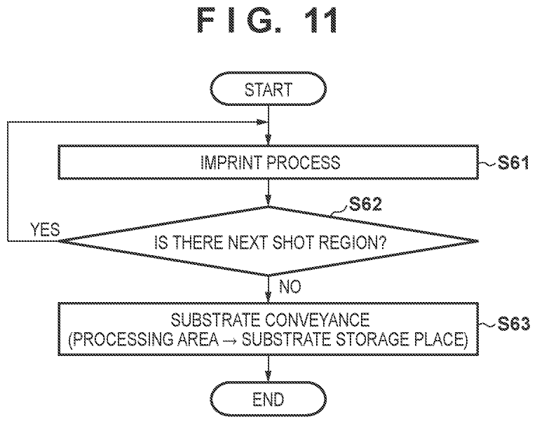

FIGS. 10 and 11 are flowcharts each illustrating the control method of the imprint apparatus IMP in this embodiment. FIG. 10 is a flowchart showing a control example of the measurement area 22 (measurement mechanism). FIG. 11 is a flowchart showing a control example of each processing areas 21 (processing mechanism). The flowchart shown in FIG. 10 and the flowchart shown in FIG. 11 are executed in parallel. Each step of the flowcharts shown in FIGS. 10 and 11 can be performed by the control unit CNT.

First, the control example of the measurement area 22 will be described with reference to FIG. 10. In step S51, the control unit CNT controls a substrate conveyance mechanism (not shown) to convey the substrate 6 from a substrate storage place to the measurement area 22 (measurement mechanism). In step S52, the control unit CNT executes the substrate measurement process using the measurement mechanism (observation scope 14) in the measurement area 22. The substrate measurement process in step S52 includes a process of irradiating the substrate 6 with light and measuring the reflection intensity index of the substrate 6.

In step S53, the control unit CNT determines whether the reflection intensity index measured in step S52 falls within an allowable range. If the reflection intensity index falls within the allowable range, the control unit CNT determines that a predetermined preprocess necessary for executing the imprint process has been executed on the substrate 6, and advances to step S54. In step S54, the control unit CNT selects (decides), from the plurality of processing areas 21, the processing area 21 to which the substrate 6 is to be conveyed. For example, the control unit CNT obtains information indicating the status of the imprint process in each processing area 21 and, based on the information, selects (decides), as the conveyance destination of the substrate 6, the processing area 21 where the imprint process finishes earliest among the plurality of processing areas 21. Then, in step S55, the control unit CNT conveys the substrate 6 onto the substrate stage 4 in the processing area 21 decided as the conveyance destination of the substrate 6 in step S54.

On the other hand, if the reflection intensity index falls outside the allowable range in step S53, the control unit CNT determines that the predetermined preprocess has not been executed on the substrate 6, and advances to step S56. In step S56, the control unit CNT executes a stop process of stopping execution of the imprint process on the substrate 6. As has been described in the first embodiment, the stop process can include notifying that the predetermined preprocess has not been executed on the substrate 6. Then, in step S57, the control unit CNT controls the substrate conveyance mechanism (not shown) to convey the substrate 6 from the measurement area 22 to the substrate storage place. In this case, the substrate 6 is not conveyed to the processing area 21.

In step S58, the control unit CNT determines whether there is the next substrate 6. If there is the next substrate 6, the process returns to step S51. If there is no next substrate 6, the process ends.

Next, the control example of each processing area 21 will be described with reference to FIG. 11. In step S61, the control unit CNT executes the imprint process on the target shot region on the substrate 6 conveyed from the measurement area 22. Since step S61 is a step similar to step S34 of FIG. 4 and step S13 of FIG. 2 described above, a detailed description is omitted here. Then, in step S62, the control unit CNT determines whether there is a next shot region on the substrate 6. If there is a next shot region, the control unit CNT repeats step S61. After executing the imprint processes on all of a plurality of shot regions on the substrate 6, the control unit CNT advances to step S63. In step S63, the control unit CNT controls the substrate conveyance mechanism (not shown) to convey the substrate 6 from the processing area (substrate stage 4) to the substrate storage place.

As has been described above, in this embodiment, in the measurement area 22, the reflection intensity index of the substrate 6 is measured and, based on the reflection intensity index, it is determined whether the predetermined preprocess necessary for executing the imprint process has been executed on the substrate 6. Then, the substrate 6 that has been determined to have undergone the predetermined preprocess is conveyed to the processing area 21, and the imprint process is executed on the substrate 6 in the processing area 21. With this, it is possible to avoid that the imprint process (molding process) is executed on the substrate 6 which has not undergone the predetermined preprocess properly.

### Embodiment of Article Manufacturing Method

An article manufacturing method according to the embodiment of the present invention is suitable for manufacturing an article, for example, a microdevice such as a semiconductor device or a device having a microstructure. The article manufacturing method according to this embodiment includes a molding step of molding, using the above-described molding apparatus (imprint apparatus or planarization apparatus), a composition on a substrate, a processing step of processing the substrate having the composition molded in the molding step, and a manufacturing step of manufacturing an article from the substrate processed in the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product molded using the above-described molding apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are a mold for imprint and the like.

The pattern of the cured product is directly used as the constituent member of at least some of the above-described articles or used temporarily as a resist mask. After etching or ion implantation is performed in the substrate processing step, the resist mask is removed.

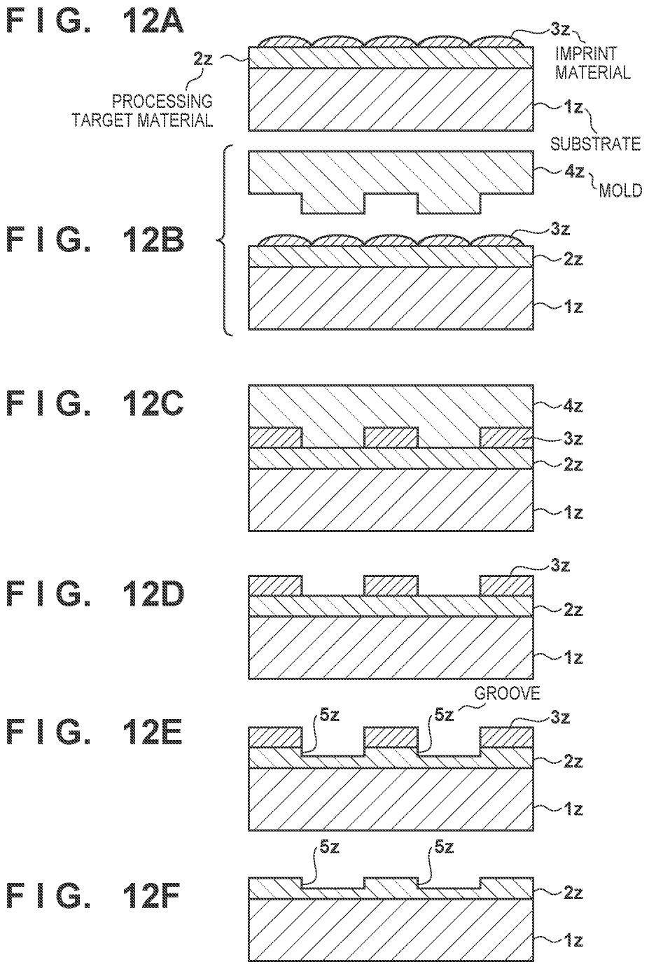

Next, a specific method of manufacturing an article using an imprint apparatus as the molding apparatus will be described. As shown in FIG. 12A, a substrate 1z such as a silicon wafer with a target material 2z to be processed, such as an insulator, formed on the surface is prepared. Next, an imprint material 3z is applied to the surface of the target material 2z by an inkjet method or the like. A state in which the imprint material 3z is applied as a plurality of droplets onto the substrate is shown here.

As shown in FIG. 12B, a side of a mold 4z for imprint, where a pattern having concave and convex portions is formed, is directed to face the imprint material 3z on the substrate. As shown in FIG. 12C, the mold 4z and the substrate 1z to which the imprint material 3z is applied are brought into contact with each other, and a pressure is applied. The gap between the mold 4z and the target material 2z is filled with the imprint material 3z. In this state, by irradiating the imprint material 3z with energy for curing through the mold 4z, the imprint material 3z is cured.

As shown in FIG. 12D, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the pattern having concave and convex portions in the mold 4z is transferred to the imprint material 3z.

As shown in FIG. 12E, by performing etching using the pattern of the cured product as an etching resistant mask, a portion of the surface of the target material 2z where the cured product does not exist or remains thin is removed to form a groove 5z. As shown in FIG. 12F, by removing the pattern of the cured product, an article with the grooves 5z formed in the surface of the target material 2z can be obtained. Here, the pattern of the cured product is removed. However, instead of removing the pattern of the cured product after processing, it may be used as, for example, an interlayer dielectric film included in a semiconductor element or the like, that is, a constituent member of an article.

### Embodiment of Planarization Process

In the above-described embodiment, a circuit pattern transfer mold on which a pattern having concave and convex portions is formed has been described as the mold. However, the mold may be a mold (plane template) having, as the contact surface, a flat surface where no pattern having concave and convex portions is formed. The plane template is used in a planarization apparatus (molding apparatus) that performs a planarization process (molding process) of performing molding such that a composition on a substrate is planarized by the flat surface. The planarization process includes a step of curing a curable composition by light irradiation or heating in a state in which the flat surface (contact surface) of the plane template is in contact with the curable composition supplied onto the substrate. As described above, this embodiment can be applied to a molding apparatus configured to mold a composition on a substrate using a plane template.

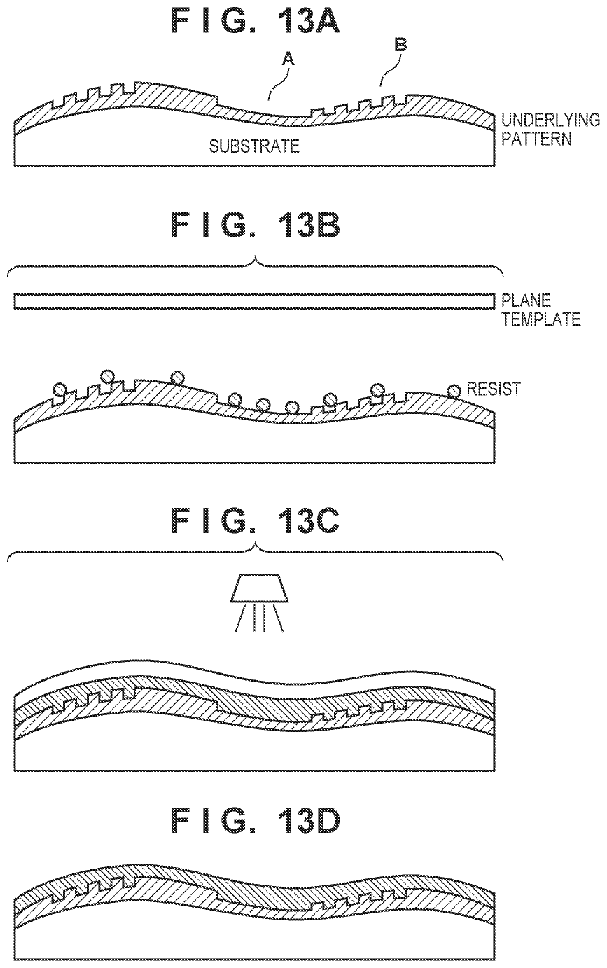

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 13A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Pat. No. 9,415,418 proposes a technique of forming a continuous film by application of a resist serving as a planarization layer by an inkjet dispenser and pressing by a plane template. Also, U.S. Pat. No. 8,394,282 proposes a technique of reflecting a topography measurement result on a substrate side on density information for each position to instruct application by an inkjet dispenser. An imprint apparatus IMP can particularly be applied as a planarization processing (planarization) apparatus for performing local planarization in a substrate surface by pressing a plane template as the mold against an uncured resist applied in advance.

FIG. 13A shows a substrate before planarization processing. In the isolated pattern region A, the area of a pattern convex portion is small. In the repetitive dense pattern region B, the ratio of the area of a pattern convex portion to the area of a pattern concave portion is 1:1. The average height of the isolated pattern region A and the repetitive dense pattern region B changes depending on the ratio of the pattern convex portion.

FIG. 13B shows a state in which the resist that forms the planarization layer is applied to the substrate. FIG. 13B shows a state in which the resist is applied by an inkjet dispenser based on the technique proposed in U.S. Pat. No. 9,415,418. However, a spin coater may be used to apply the resist. In other words, the imprint apparatus IMP can be applied if a step of pressing a plane template against an uncured resist applied in advance to planarize the resist is included.

As shown in FIG. 13C, the plane template is made of glass or quartz that passes ultraviolet light, and the resist is cured by irradiation of ultraviolet light from a light source. For the moderate unevenness of the entire substrate, the plane template conforms to the profile of the substrate surface. After the resist is cured, the plane template is separated from the resist, as shown in FIG. 13D.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-115052 filed on Jul. 19, 2022, which is hereby incorporated by reference herein in its entirety.

What is claimed is:

1. A method of executing a molding process of molding a composition on a substrate using a member, the method comprising:
obtaining, by irradiating the substrate with light, an index indicating an intensity of reflected light from the substrate;
determining, based on the index obtained in the obtaining, whether a predetermined preprocess necessary for executing the molding process has been executed on the substrate; and
executing the molding process on the substrate in a case of determining that the preprocess has been executed on the substrate.

2. The method according to claim 1, wherein
in the obtaining, the index is obtained for each of a plurality of portions on the substrate, and
in the determining, it is determined, based on a representative value of the indices obtained for the plurality of portions in the obtaining, whether the preprocess has been executed on the substrate.

3. The method according to claim 1, wherein
in the obtaining, at least one of an illuminance and a contrast of an image obtained by capturing an image of the substrate is obtained as the index.

4. The method according to claim 1, wherein
in the obtaining, at least one of an illuminance and a contrast of an image obtained by capturing an image of a mark provided on the substrate is obtained as the index.

5. The method according to claim 1, wherein
in the obtaining, a change rate of the intensity of the reflected light obtained by changing an irradiation condition for irradiating the substrate with the light is obtained as the index.

6. The method according to claim 5, wherein
the irradiation condition includes at least one of an intensity and a wavelength of the light with which the substrate is irradiated.

7. The method according to claim 1, wherein
in the determining, based on whether the index obtained in obtaining falls within an allowable range, it is determined whether the preprocess has been executed on the substrate.

8. The method according to claim 7, wherein
the allowable range is set using a reference substrate having undergone the preprocess and having not undergone the molding process.

9. The method according to claim 1, further comprising
calibrating a measurement condition for measuring the index in the obtaining,
wherein in the calibrating, the measurement condition is calibrated such that the index measured under the measurement condition for an object different from the substrate falls within a target range.

10. The method according to claim 9, wherein
the object is a stage configured to hold the substrate, and
in the calibrating, the measurement condition is calibrated such that the index measured under the measurement condition for a reference mark provided on the stage falls within the target range.

11. The method according to claim 1, further comprising
notifying, in a case of determining that the preprocess has not been executed on the substrate, that the preprocess has not been executed on the substrate without executing the molding process on the substrate.

12. The method according to claim 1, further comprising
deciding, in a case of determining that the preprocess has been executed on the substrate, a processing unit to be used to execute the molding process among a plurality of processing units each configured to execute the molding process,
wherein the executing the molding process is executed in the processing unit decided in the deciding.

13. The method according to claim 12, wherein
a time required from the obtaining to the determination in the determining is shorter than a time required for the executing the molding process.

14. A method of executing a molding process of molding a composition on a substrate using a member, the method comprising:
obtaining, by irradiating the substrate with light, an index indicating an intensity of reflected light from the substrate;
determining, based on the index obtained in the obtaining, a state of the substrate, and
executing the molding process on the substrate in accordance with a result determined in the determining,
wherein in the obtaining, a change rate of the intensity of the reflected light obtained by changing an irradiation condition for irradiating the substrate with the light is obtained as the index.

15. A molding apparatus that molds a composition on a substrate using a member, the apparatus comprising:
an obtainment unit configured to obtain, by irradiating the substrate with light, an index indicating an intensity of reflected light from the substrate; and
a control unit configured to control a molding process of molding the composition on the substrate using the member,
wherein the control unit
determines, based on the index obtained by the obtainment unit, whether a preprocess necessary for executing the molding process has been executed on the substrate, and
executes, in a case of determining that the preprocess has been executed on the substrate, the molding process on the substrate.

16. The molding apparatus according to claim 15, wherein
the member includes a pattern to be transferred to the composition on the substrate, and
the molding apparatus is configured to form the pattern in the composition on the substrate by bringing the member into contact with the composition on the substrate.

17. The molding apparatus according to claim 15, wherein
the member includes a flat surface, and
the molding apparatus is configured to planarize the composition on the substrate by bringing the member into contact with the composition on the substrate.

18. An article manufacturing method comprising:
molding a composition on a substrate using a molding apparatus defined in claim 15;
processing the substrate with the composition molded in the molding; and
manufacturing an article from the substrate processed in the processing.
